(19) United States
(12) Patent Application Publication
(10) Pub. No.: US 2025/0212662 A1
(43) Pub. Date: Jun. 26, 2025

(54) DISPLAY DEVICE AND METHOD OF MANUFACTURING THE SAME

(71) Applicant: Samsung Display Co., LTD., Yongin-si (KR)

(72) Inventor: Hyun Seung LEE, Yongin-si (KR)

(21) Appl. No.: 18/770,343

(22) Filed: Jul. 11, 2024

(30) Foreign Application Priority Data
Dec. 21, 2023 (KR) 10-2023-0188430

(51) Int. Cl. H10K 59/80; H10K 59/12; H10K 59/35

(52) U.S. Cl. CPC H10K 59/879; H10K 59/1201; H10K 59/353

(57) ABSTRACT

A display device includes: a substrate; a pixel circuit layer on the substrate; a light emitting layer on the pixel circuit layer and including light emitting elements; a color filter layer on the light emitting layer and including color filters; and a lens array on the color filter layer, wherein the lens array includes a plurality of lenses having convex shapes in a direction opposite to a direction toward the substrate, and the plurality of lenses include a negative photoresist composition.

### CROSS-REFERENCE TO RELATED APPLICATION

The present application claims priority to and the benefit of Korean Patent Application No. 10-2023-0188430, filed on Dec. 21, 2023, in the Korean Intellectual Property Office, the entire disclosure of which is incorporated herein by reference.

### BACKGROUND OF THE INVENTION

### 1. Field

Aspects of some embodiments of the present disclosure relate to a display device and a method of manufacturing the same.

### 2. Description of the Related Art

Recently, as consumer interest in an information display is increasing, research and development for display devices is being continuously conducted. Particularly, micro lenses may be used to increase resolution on each pixel included in the display device.

Recently, due to the down-sizing of optical components and the development of application technology, application devices using micro-sized lens arrays in conventional geometric optical-based lenses may be applied to display devices related to AR/VR.

The above information disclosed in this Background section is only for enhancement of understanding of the background and therefore the information discussed in this Background section does not necessarily constitute prior art.

### SUMMARY OF THE INVENTION

Aspects of some embodiments of the present disclosure include a display device with relatively improved reliability. For example, the display device may relatively improve the reliability of a micro lens by forming a fine pattern through a photo lithography process without a separate etching process.

Aspects of some embodiments of the present disclosure include a method of manufacturing a display device with relatively improved reliability.

According to some embodiments of the present disclosure, a display device includes: a substrate; a pixel circuit layer on the substrate; a light emitting layer on the pixel circuit layer and including light emitting elements; a color filter layer on the light emitting layer and including color filters; and a lens array on the color filter layer, wherein the lens array includes a plurality of lenses having convex shapes in a direction opposite to a direction toward the substrate, and the plurality of lenses include a negative photoresist composition.

According to some embodiments, the plurality of lenses may include an optically transparent material.

According to some embodiments, the plurality of lenses may respectively overlap the color filters.

According to some embodiments, the color filters may include a first color filter, a second color filter, and a third color filter to be spaced apart from each other in a first direction, the plurality of lenses may include a first lens on the first color filter, a second lens on the second color filter, and a third lens on the third color filter, and each of the first to third lenses may have a convex shape.

According to some embodiments, the color filters may respectively overlap the light emitting elements.

According to some embodiments of the present disclosure, in a method of manufacturing a display device, the method includes: forming a light emitting layer on a substrate; forming a color filter layer including color filters on the light emitting layer; and forming a lens array on the color filter layer, wherein the lens array includes a plurality of lenses having convex shapes in a direction opposite to a direction toward the substrate, wherein the forming of the lens array includes forming banks on the color filter layer; filling an optically transparent material between the banks; entirely exposing the banks and the optically transparent material; removing, by developing the exposed banks and the exposed optically transparent material, the exposed banks while leaving the exposed optically transparent material; and curing the remaining optically transparent material to form the plurality of lenses.

According to some embodiments, the plurality of lenses may include a negative photoresist composition.

According to some embodiments, by curing the remaining optically transparent material using heat, the convex shapes of the plurality of lenses may be formed.

According to some embodiments, the plurality of lenses may respectively overlap the color filters.

According to some embodiments, the forming of the banks may include applying a photoresist on the color filter layer; exposing the photoresist using a mask; and developing the exposed photoresist to form the banks.

According to some embodiments, each of the banks may have a reverse tapered shape.

According to some embodiments, the banks may include a positive photoresist composition.

According to some embodiments, the banks may include a liquid-repellent material.

According to some embodiments, a portion adjacent to an upper surface of each of the banks may have hydrophobicity.

According to some embodiments, the color filters may include a first color filter, a second color filter, and a third color filter spaced apart from each other in a first direction, and the banks may include a first bank overlapping between the first color filter and the second color filter and a second bank overlapping between the second color filter and the third color filter.

According to some embodiments, the optically transparent material may be in direct contact with the second color filter between the first bank and the second bank.

According to some embodiments, the plurality of lenses may include a first lens on the first color filter, a second lens on the second color filter, and a third lens on the third color filter, and each of the first to third lenses may have a convex shape.

### BRIEF DESCRIPTION OF DRAWINGS

FIG. 1 illustrates a block diagram of a display device according to some embodiments of the present disclosure.

FIG. 2 illustrates a top plan view of a display panel of FIG. 1 according to some embodiments.

FIG. 3 illustrates a cross-sectional view of a display panel of FIG. 1 according to some embodiments.

FIG. 4 illustrates a block diagram of one of sub-pixels of FIG. 2 according to some embodiments.

FIG. 5 illustrates a top plan view of one of pixels of FIG. 2 according to some embodiments.

FIG. 6 illustrates a cross-sectional view taken along the line I-I′ of FIG. 5.

FIG. 7 illustrates a top plan view of one of pixels of FIG. 2 according to some embodiments.

FIG. 8 illustrates a top plan view of one of pixels of FIG. 2 according to some embodiments.

FIG. 9 illustrates a flowchart of a method of manufacturing the display device of FIG. 6 according to some embodiments.

FIG. 10 illustrates a cross-sectional view of a display device in operation S1020 of FIG. 9.

FIG. 11 to FIG. 13 illustrate cross-sectional views of a display device for explaining aspects of the operation S1031 of FIG. 9.

FIG. 14 illustrates a cross-sectional view of a display device in operation S1033 of FIG. 9.

FIG. 15 illustrates a cross-sectional view of a display device in operation S1034 of FIG. 9.

FIG. 16 illustrates a cross-sectional view of a display device in operation S1035 of FIG. 9.

### DETAILED DESCRIPTION

Hereinafter, aspects of some embodiments of the present disclosure will be described in more detail with reference to the accompanying drawings. The following description is intended to provide only a sufficient disclosure to enable the understanding of the operation of the invention, and any other disclosure is omitted to avoid obscuring the scope of the invention. In addition, the inventive concept may be embodied in different forms and is not limited to the embodiments set forth herein. The embodiments described herein are provided for the purpose of describing the technical concept of the invention in sufficient detail for those skilled in the art to easily practice it.

Throughout the specification, when it is described that an element is “connected” to another element, this includes not only being “directly connected”, but also being “indirectly connected” with another device in between. The terms used herein are for the purpose of describing specific embodiments and are not intended to limit the scope of the invention. Throughout the specification, unless explicitly described to the contrary, the word “comprise” and variations such as “comprises” or “comprising” will be understood to imply the inclusion of stated elements but not the exclusion of any other elements. For the purposes of this disclosure, “at least one of X, Y, or Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms first, second, etc. may be used herein to describe various constituent elements, these constituent elements should not be limited by these terms. These terms are used to distinguish one constituent element from another. Thus, a first constituent element discussed below could be termed a second constituent element without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (for example, rotated 90 degrees or at other orientations), and, as such, the spatially relative descriptors used herein interpreted accordingly.

Various embodiments are described herein with reference to sectional illustrations that are schematic illustrations of idealized embodiments. As such, variations from the shapes of the illustrations as a result, for example, of manufacturing techniques and/or tolerances, are to be expected. Thus, the embodiments disclosed herein should not be construed as limited to the particular illustrated shapes of regions, but are to include deviations in shapes that result from, for instance, manufacturing. Thus, the regions illustrated in the drawings are schematic in nature and their shapes are not intended to illustrate the actual shape of a region of a device and are not intended to be limiting.

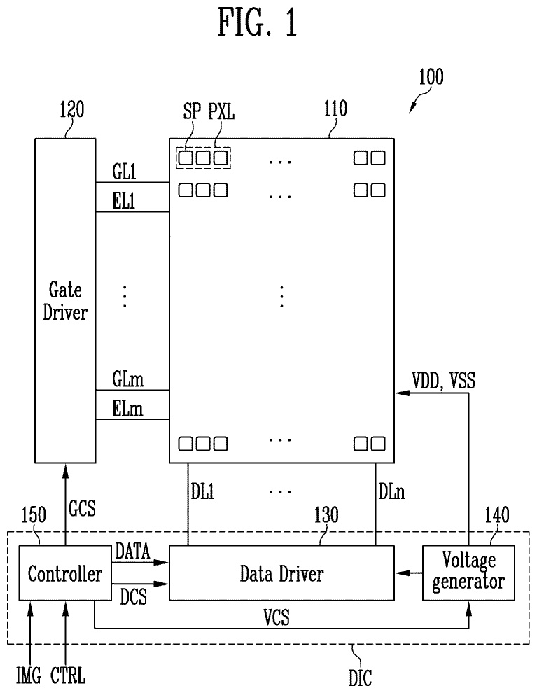

FIG. 1 illustrates a block diagram of a display device according to some embodiments of the present disclosure.

Referring to FIG. 1, a display device 100 may include a display panel 110, a gate driver 120, a data driver 130, a voltage generator 140, and a controller 150.

The display panel 110 may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

Each of the sub-pixels SP may include at least one light emitting element configured to generate light. Accordingly, the sub-pixels SP may respectively generate light of a specific color, such as red, green, blue, cyan, magenta, yellow, or the like. Two or more of the sub-pixels SP may configure one pixel PXL. For example, as shown in FIG. 1, three sub-pixels may configure one pixel PXL.

The gate driver 120 may be connected to the sub-pixels SP arranged in a row direction through the first to m-th gate lines GL1 to GLm. The gate driver 120 may output gate signals to the first to m-th gate lines GL1 to GLm in response to a gate control signal GCS. According to some embodiments, the gate control signal GCS may include a start signal indicating the start of each frame, a horizontal synchronization signal for outputting gate signals in synchronization with the timing at which data signals are applied, and the like.

According to some embodiments, first to m-th light emitting control lines EL1 to ELm connected to the sub-pixels SP in a row direction may be further provided. In this case, the gate driver 120 may include a light emitting control driver configured to control the first to m-th light emitting control lines EL1 to ELm, and the light emitting control driver may operate under the control of the controller 150.

The gate driver 120 may be located on one side of the display panel 110. However, embodiments according to the present disclosure are not limited thereto. For example, the gate driver 120 may be divided into two or more physically and/or logically separated drivers, and the drivers may be located on one side of the display panel 110 and the other side of the display panel 110 opposite to the one side. As described above, the gate driver 120 may be arranged around the display panel 110 in various forms according to the embodiments.

The data driver 130 may be connected to the sub-pixels SP arranged in a column direction through the first to n-th data lines DL1 to DLn. The data driver 130 may receive image data (DATA) and a data control signal DCS from the controller 150. The data driver 130 may operate in response to the data control signal DCS. According to some embodiments, the data control signal DCS may include a source start pulse, a source shift clock, a source output enable signal, and the like.

The data driver 130 may use voltages from the voltage generator 140 to apply data signals having grayscale voltages corresponding to the image data (DATA) to the first to n-th data lines DL1 to DLn. When a gate signal is applied to each of the first to m-th gate lines GL1 to GLm, data signals corresponding to the image data DATA may be applied to the data lines DL1 to DLm. Accordingly, the corresponding sub-pixels SP may generate light corresponding to the data signals. Accordingly, images may be displayed on the display panel 110.

According to some embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate a plurality of voltages and provide the generated voltages to constituent elements of the display device 100. For example, the voltage generator 140 may be configured to generate a plurality of voltages by receiving an input voltage from the outside of the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD May have a relatively high voltage level, and the second power voltage VSS may have a voltage level lower than the first power voltage VDD. According to some embodiments, the first power voltage VDD or the second power voltage VSS may be provided by an external device of the display device 100.

In addition, the voltage generator 140 may generate various voltages. For example, the voltage generator 140 may generate an initialization voltage applied to the sub-pixels SP. For example, during a sensing operation to sense electrical characteristics of transistors and/or light emitting elements of the sub-pixels SP, a reference voltage (e.g., a set or predetermined reference voltage) may be applied to the first to n-th data lines DL1 to DLn, and the voltage generator 140 may generate the reference voltage.

The controller 150 may control various operations of the display device 100. The controller 150 may receive input image data IMG and a control signal CTRL for controlling the display of the input image data, from the outside. The controller 150 may provide the gate control signal GCS, the data control signal DCS, and the voltage control signal VCS in response to the control signal CTRL.

The controller 150 may convert the input image data IMG to be suitable for the display device 100 or the display panel 110 to output the image data DATA. According to some embodiments, the controller 150 may output the image data DATA by aligning the input image data IMG to be suitable for the sub-pixels SP of a row unit.

Two or more constituent elements of the data driver 130, the voltage generator 140, and the controller 150 may be mounted on one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally separate constituent elements within one driver integrated circuit DIC. According to some embodiments, at least one of the data driver 130, the voltage generator 140, or the controller 150 may be provided as a constituent element separated from the driver integrated circuit DIC.

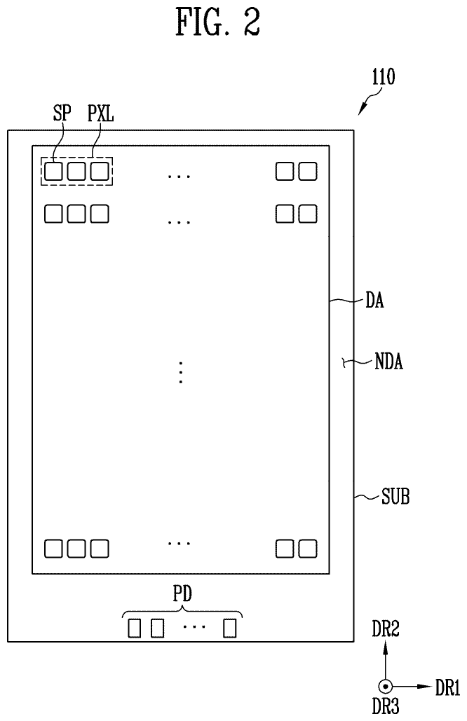

FIG. 2 illustrates a top plan view of a display panel of FIG. 1 according to some embodiments.

Referring to FIG. 2, the display panel 110 of FIG. 1 may include a display area DA and a non-display area NDA. The display panel 110 may display images at the display area DA. The non-display area NDA may be arranged around the display area DA.

The display panel 110 may include a substrate SUB, sub-pixels SP, and pads PD.

When the display panel 110 is used as a display screen for a head mounted display (HMD), a virtual reality (VR) device, a mixed reality (MR) device, or an augmented reality (AR) device, the display panel 110 may be located very close to the user's eyes. In this case, the sub-pixels SP with relatively high integration may be required. According to some embodiments, in order to increase the integration of the sub-pixels SP, the substrate SUB may be provided as a silicon substrate. The sub-pixels SP and/or the display panel 110 may be formed on the substrate SUB, which is a silicon substrate.

The sub-pixels SP may be located in the display area DA on the substrate SUB. The sub-pixels SP may be arranged in a matrix format along a first direction DR1 and a second direction DR2 that intersects the first direction DR1. However, embodiments according to the present disclosure are not limited thereto. For example, the sub-pixels SP may be arranged in a zigzag form along first direction DR1 and second direction DR2. For example, the sub-pixels SP may be arranged in a PENTILE™ shape or arrangement. The first direction DR1 may be a row direction, and the second direction DR2 may be a column direction.

Two or more of the plurality of sub-pixels SP may configure one pixel PXL.

A constituent element to control the sub-pixels SP may be located in the non-display area NDA on the substrate SUB. For example, wires connected to the sub-pixels SP, such as the first to m-th gate lines GL1 to GLm and the first to n-th data lines DL1 to DLn of FIG. 1, may be located in the non-display area NDA.

At least one of the gate driver 120, the data driver 130, the voltage generator 140, or the controller 150 in FIG. 1 may be integrated in the non-display area NDA of the display panel 110. According to some embodiments, the gate driver 120 of FIG. 1 may be mounted on the display panel 110, and may be located in the non-display area NDA. According to some embodiments, the gate driver 120 may be implemented as an integrated circuit separated from the display panel 110.

The pads PD may be located in the non-display area NDA on the substrate SUB. The pads PD may be electrically connected to the sub-pixels SP through wires. For example, the pads PD may be connected to the sub-pixels SP through the first to n-th data lines DL1 to DLn.

The pads PD may interface the display panel 110 to other constituent elements of the display device 100 (see FIG. 1). According to some embodiments, voltages and signals required for operations of constituent elements included in the display panel 110 may be provided from the driver integrated circuit DIC of FIG. 1 through the pads PD. For example, the first to n-th data lines DL1 to DLn may be connected to the driver integrated circuit DIC through the pads PD. For example, the first and second power voltages VDD and VSS may be received from the driver integrated circuit DIC through the pads PD. For example, when the gate driver 120 is mounted on the display panel 110, the gate control signal GCS may be transmitted from the driver integrated circuit DIC to the gate driver 120 through the pads PD.

According to some embodiments, the circuit board may be electrically connected to the pads PD by using a conductive adhesive member such as an anisotropic conductive film. In this case, the circuit board may be a flexible printed circuit board (FPCB) or a flexible film made of a flexible material. The driver integrated circuit DIC may be mounted on the circuit board to be electrically connected to the pads PD.

According to some embodiments, the display area DA may have various shapes. The display area DA may have a closed-loop shape including sides of a straight line and/or a curved line. For example, the display area DA may have shapes such as a polygonal shape, a circular shape, a semicircular, and an elliptical shape.

According to some embodiments, the display panel 110 may have a flat display surface. According to some embodiments, the display panel 110 may have a display surface that is at least partially round. According to some embodiments, the display panel 110 may be bendable, foldable, or rollable. In these cases, the display panel 110 and/or the substrate SUB may include materials with flexible properties.

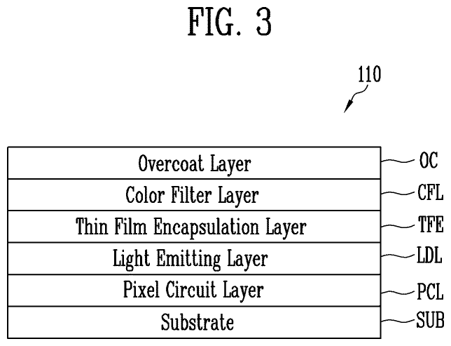

FIG. 3 illustrates a cross-sectional view of a display panel of FIG. 1 according to some embodiments.

Referring to FIG. 3, the display panel 110 may include a substrate SUB, a pixel circuit layer PCL, a light emitting layer LDL, a thin film encapsulation layer TFE, a color filter layer CFL, and an overcoat layer OC.

The substrate SUB may include a semiconductor substrate. For example, the substrate SUB may include a silicon bulk wafer, or an epitaxial wafer. The epitaxial wafer may include a crystalline material layer grown on a bulk substrate by an epitaxial process, that is, an epitaxial layer. The substrate SUB is not limited to a bulk wafer or an epitaxial wafer, but may be formed using various wafers such as a polished wafer, an annealed wafer, and a silicon-on-insulator (SOI) wafer.

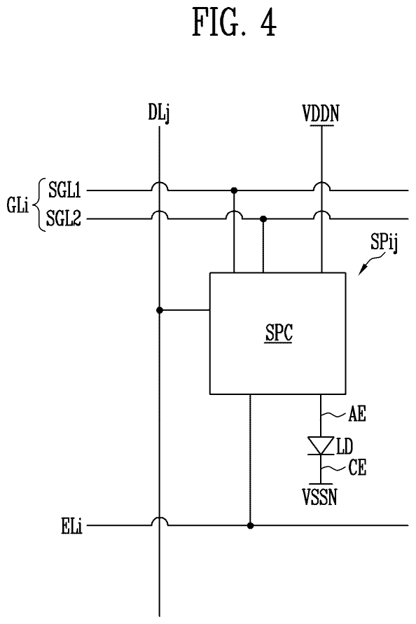

The pixel circuit layer PCL may be located on the substrate SUB. The pixel circuit layer PCL may include circuit elements of a sub-pixel circuit SPC (refer to FIG. 4) and at least one insulating layer located between the circuit elements. The circuit elements may include a plurality of transistors and signal lines connected to the transistors. For example, the transistors may be metal oxide semiconductor field effect transistors (MOSFET), but embodiments according to the present disclosure are not limited thereto. In addition, the transistor may have a structure in which a semiconductor layer, a gate electrode, and a source/drain electrode are sequentially stacked with an insulating layer interposed therebetween.

The substrate SUB and the pixel circuit layer PCL described above may be formed by applying semiconductor processes and equipment, but embodiments according to the present disclosure are not limited thereto.

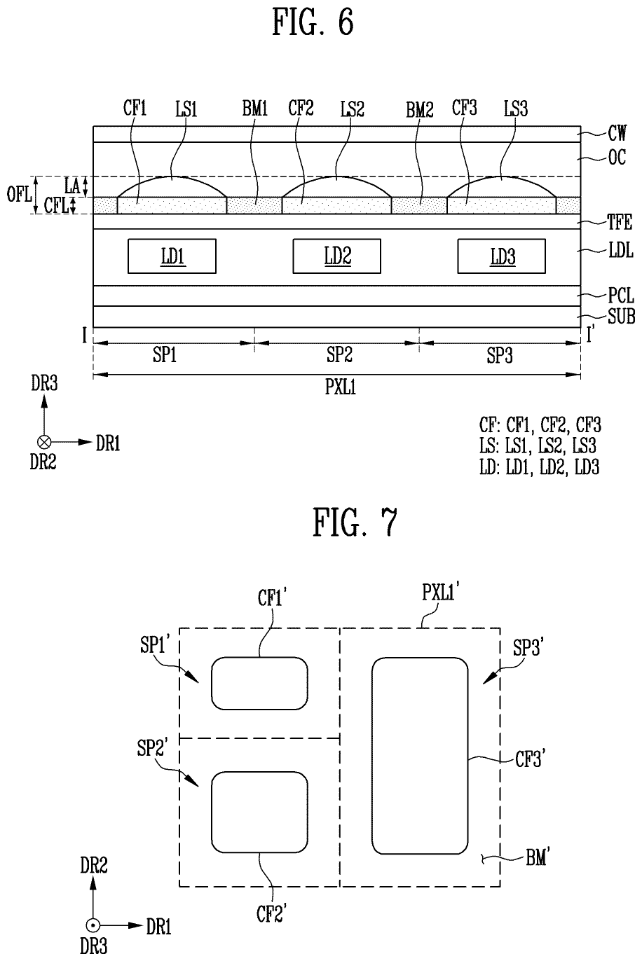

The light emitting layer LDL may include light emitting elements LD (refer to FIG. 6) that emit light. The light emitting elements LD may be located in first to third sub-pixels SP1 to SP3, respectively. According to some embodiments, the light emitting elements LD may respectively emit light of the same color. In this case, due to the color filter layers CFL of different colors located on respective light emitting elements LD, the first to third sub-pixels SP1 to SP3 may emit light of different colors. According to some embodiments, the light emitting elements LD may respectively emit different colors of light. However, the color, type, and the like of the light emitting elements LD of the light emitting layer LDL are not limited.

The thin film encapsulation layer TFE may be located on the light emitting layer LDL. The thin film encapsulation layer TFE may cover the light emitting layer LDL to prevent or reduce instances of contaminants such as external air and moisture penetrating into the light emitting elements LD.

The color filter layer CFL may be located on the thin film encapsulation layer TFE. The color filter layer CFL may include color filters that selectively transmit light of one color. That is, the color filter layer CFL may selectively transmit the light emitted from the light emitting elements LD in an image display direction (or a front direction) of the display panel 110, but is not limited thereto.

According to some embodiments, a lens array LA (see FIG. 6) may be located on the color filter layer CFL. The lens array LA may include a plurality of lenses, and the lenses may be arranged to correspond to respective sub-pixels SP. The lens array LA may serve to increase extraction efficiency of light emitted from the light emitting elements LD.

The overcoat layer OC may be located on the pixels PXL having the above-described constituent elements. The overcoat layer OC may prevent or reduce instances of contaminants or impurities such as moisture or air penetrating from the outside to damage or contaminate color filters CF (see FIG. 6). In addition, the overcoat layer OC may prevent or reduce instances of the material of the color filters CF diffusing into other constituent elements. However, it has been described as an example that the overcoat layer OC is not included in each of the pixels PXL and is a separate constituent element, but embodiments according to the present disclosure are not limited thereto. The overcoat layer OC may be a partial constituent element included in each of the pixels PXL.

FIG. 4 illustrates a block diagram of an example of one of sub-pixels of FIG. 2. In FIG. 4, among the sub-pixels SP of FIG. 2, a sub-pixel SPij located in an i-th row (i is an integer greater than or equal to 1 and less than or equal to m) and a j-th column (j is an integer greater than or equal to 1 and less than or equal to n) is illustrated as an example.

Referring to FIG. 4, the sub-pixel SPij may include a sub-pixel circuit SPC and a light emitting element LD.

The light emitting element LD may be connected between a first power voltage node VDDN and a second power voltage node VSSN. In this case, the first power voltage node VDDDN may be a node that transmits the first power voltage VDD of FIG. 1, and the second power voltage node VSSN may be a node that transmits the second power voltage VSS of FIG. 1.

An anode electrode AE of the light emitting element LD may be connected to the first power voltage node VDDN through the sub-pixel circuit SPC, and a cathode electrode CE of the light emitting element LD may be connected to the second power voltage node VSSN. For example, the anode electrode AE of the light emitting element LD may be connected to the first power voltage node VDDN through one or more transistors included in the sub-pixel circuit SPC.

The sub-pixel circuit SPC may be connected to an i-th gate line GLi among the first to m-th gate lines GL1 to GLm of FIG. 1, an i-th light emitting control line ELi among the first to m-th light emitting control lines EL1 to ELm of FIG. 1, and a j-th data line DLj among the first to n-th data lines DL1 to DLn of FIG. 1. The sub-pixel circuit SPC may be configured to control the light emitting element LD according to signals received through these signal lines.

The sub-pixel circuit SPC may operate in response to a gate signal received through the i-th gate line GLi. The i-th gate line GLi may include one or more sub-gate lines. In the embodiments, as shown in FIG. 2, the i-th gate line GLi may include first and second sub-gate lines SGL1 and SGL2. The sub-pixel circuit SPC may operate in response to gate signals received through the first and second sub-gate lines SGL1 and SGL2. As such, when the i-th gate line GLi includes two or more sub-gate lines, the sub-pixel circuit SPC may operate in response to gate signals received through the corresponding sub-gate lines.

The sub-pixel circuit SPC may operate in response to a light emitting control signal received through the i-th light emitting control line ELi. In the embodiments, the i-th light emitting control line ELi may include one or more sub-light emitting control lines. When the i-th light emitting control line ELi includes two or more sub-light emitting control lines, the sub-pixel circuit SPC may operate in response to light emitting control signals received through the corresponding sub-light emitting control lines.

The sub-pixel circuit SPC may receive a data signal through the j-th data line DLj. The sub-pixel circuit SPC may store a voltage corresponding to the data signal in response to at least one of the gate signals received through the first and second sub-gate lines SGL1 and SGL2. In response to the light emitting control signal received through the i-th light emitting control line ELi, the sub-pixel circuit SPC may adjust the current flowing from the first power voltage node VDDN to the second power voltage node VSSN through the light emitting element LD according to the stored voltage. Accordingly, the light emitting element LD may generate light of luminance corresponding to the data signal.

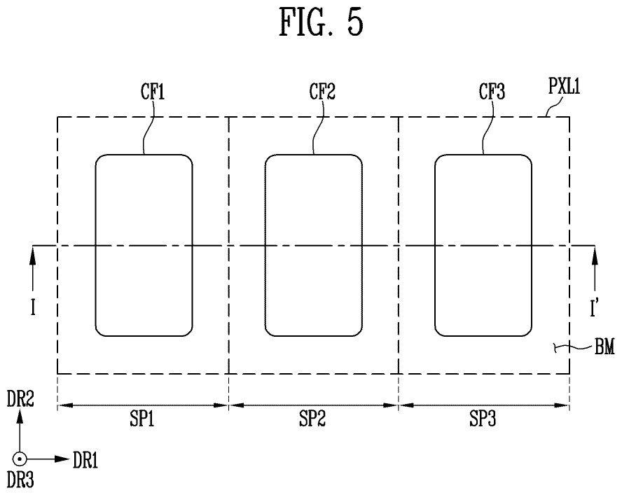

FIG. 5 illustrates a top plan view of one of pixels of FIG. 2 according to some embodiments.

Referring to FIG. 5, a first pixel PXL1 may include the first to third sub-pixels SP1 to SP3 arranged in the first direction DR1. In addition, the first to third sub-pixels SP1 to SP3 may include first to third color filters CF1 to CF3, respectively.

The first sub-pixel SP1 may include a first color filter CF1 and a black matrix BM around the first color filter CF1. The second sub-pixel SP2 may include a second color filter CF2 and a black matrix BM around the second color filter CF2. The third sub-pixel SP3 may include a third color filter CF3 and a black matrix BM around the third color filter CF3. However, the black matrix BM around the first to third color filters CF1 to CF3 may be omitted. For example, when the black matrix BM is omitted, the first to third color filters CF1 to CF3 may be arranged so that the first to third color filters at least partially overlap each other. Alternatively, the first to third color filters CF1 to CF3 may be arranged to be in contact with each other.

The first color filter CF1 may be located in an area overlapping a light emitting area where light is emitted from the first sub-pixel SP1. The first color filter CF1 may selectively transmit light of a first color. For example, the first color filter CF1 may include a color filter material of the first color that transmits light of the first color and blocks light in the second and third colors. As such, the first color filter CF1 may be understood as a light emitting area in which light emitted from the first sub-pixel SP1 is outputted.

The second color filter CF2 may be located in an area overlapping a light emitting area where light is emitted from the second sub-pixel SP2. The second color filter CF2 may selectively transmit light of a second color. For example, the second color filter CF2 may include a color filter material of the second color that transmits light of the second color and blocks light of the first and third colors. As such, the second color filter CF2 may be understood as a light emitting area in which light emitted from the second sub-pixel SP2 is outputted.

The third color filter CF3 may be located in an area overlapping a light emitting area where light is emitted from the third sub-pixel SP3. The third color filter CF3 may selectively transmit light of a third color. For example, the third color filter CF3 may include a color filter material of the third color that transmits light of the third color and blocks light of the first and second colors. As such, the third color filter CF3 may be understood as a light emitting area in which light emitted from the third sub-pixel SP3 is outputted.

In addition, according to some embodiments, a first lens LS1 (see FIG. 6) may be arranged to overlap the first color filter CF1 of the first sub-pixel SP1. A second lens LS2 (see FIG. 6) may be arranged to overlap the second color filter CF2 of the second sub-pixel SP2. A third lens LS3 (see FIG. 6) may be arranged to overlap the third color filter CF3 of the third sub-pixel SP3.

FIG. 6 illustrates a cross-sectional view taken along line I-I′ of FIG. 5.

Referring to FIG. 6, the first pixel PXL1 may include a substrate SUB, a pixel circuit layer PCL, a light emitting layer LDL, a thin film encapsulation layer TFE, an optical functional layer OFL, an overcoat layer OC, and a cover window CW. In addition, the optical functional layer OFL may include a color filter layer CFL and a lens array LA.

The light emitting layer LDL including first to third light emitting elements LD1 to LD3 may be located on the substrate SUB. In addition, the pixel circuit layer PCL may be located between the substrate SUB and the light emitting layer LDL.

The pixel circuit layer PCL may include various driving elements and wiring for driving the first to third light emitting elements LD1 to LD3. For example, the pixel circuit layer PCL may include transistors and storage capacitors included in the sub-pixel circuit SPC (refer to FIG. 4) of each of the first to third sub-pixels SP1 to SP3. For example, the pixel circuit layer PCL may further include wires such as scan lines and data lines connected to the first to third sub-pixels SP1 to SP3 of each pixel. In addition, the pixel circuit layer PCL may include various constituent elements, and embodiments are not limited thereto.

The light emitting layer LDL may include a first light emitting element LD1 located in the first sub-pixel SP1, a second light emitting element LD2 located in the second sub-pixel SP2, and a third light emitting element LD3 located in the third sub-pixel SP3. According to some embodiments, each of the first to third light emitting elements LD1 to LD3 may include a self-emissive element such as an organic light emitting diode. For example, each of the first to third light emitting elements LD1 to LD3 may have a structure in which an anode electrode AE (see FIG. 4), a hole transport layer, an organic light emitting layer, an electron transport layer, and a cathode electrode CE (see FIG. 4) are sequentially stacked, but is not limited thereto. For example, each of the first to third light emitting elements LD1 to LD3 may include an inorganic light emitting element including an inorganic light emitting material or a light emitting element (quantum dot display element) that emits light by changing the wavelength of light emitted using quantum dots.

According to some embodiments, the anode electrode AE may be patterned and formed for each of the first to third sub-pixels SP1 to SP3. Since the anode electrode AE supplies holes to the organic light emitting layer, the anode electrode AE may be made of a transparent conductive material having a high work function. For example, the anode electrode AE may be made of a transparent conductive material such as a tin oxide (TO), a zinc oxide (ZnO), an indium tin oxide (ITO), an indium zinc oxide (IZO), an indium zinc oxide (ITZO) and the like, but is not limited thereto.

The organic light emitting layer may be located between the anode electrode AE and the cathode electrode CE. The organic light emitting layer may emit light by combining electrons and holes supplied from the anode electrode AE and the cathode electrode CE.

The cathode electrode CE may be located on the organic light emitting layer. The cathode electrode CE may be formed as one layer throughout the entire surface of the substrate SUB. Respective cathode electrodes CE of the first to third sub-pixels SP1 to SP3 may be connected to each other to be integrally formed. Since the cathode electrode CE supplies electrons to the organic light emitting layer, the cathode electrode CE may include a conductive material having a low work function. For example, the cathode electrode CE may be made of a transparent conductive material such as a tin oxide (TO), a zinc oxide (ZnO), an indium tin oxide (ITO), an indium zinc oxide (IZO), an indium zinc oxide (ITZO), and the like, or a ytterbium (Yb) alloy. In addition, the cathode electrode CE may be made of a metal material such as silver (Ag), copper (Cu), an magnesium-silver (Mg—Ag) alloy, or a very thin metal material, but is not limited thereto.

The thin film encapsulation layer TFE may be located on the light emitting layer LDL. The thin film encapsulation layer TFE may be an encapsulation substrate or a multi-layered encapsulation film. When the thin film encapsulation layer TFE is in a form of the encapsulation film, it may include an inorganic film and/or an organic film. For example, the thin film encapsulation layer TFE may have a structure in which an inorganic film, an organic film, and an inorganic film are sequentially stacked. The thin film encapsulation layer TFE may prevent or reduce instances of contaminants such as external air and moisture penetrating into the light emitting layer LDL and the pixel circuit layer PCL.

The optical functional layer OFL may be located on the thin film encapsulation layer TFE. The optical functional layer OFL may include a color filter layer CFL and a lens array LA. According to some embodiments, the optical functional layer OFL may be attached to the encapsulation layer TFE through an adhesive layer. For example, the optical functional layer OFL may be separately manufactured to be attached to the encapsulation layer TFE through an adhesive layer.

The color filter layer CFL may be located on the thin film encapsulation layer TFE. The color filter layer CFL may include first to third color filters CF1 to CF3 located in the first direction DR1. The first color filter CF1 may be located in the first sub-pixel SP1, the second color filter CF2 may be located in the second sub-pixel SP2, and the third color filter CF3 may be located in the third sub-pixel SP3.

For example, the first color filter CF1 may overlap the first light emitting element LD1 on one surface of the thin film encapsulation layer TFE. The second color filter CF2 may overlap the second light emitting element LD2 on one surface of the thin film encapsulation layer TFE. The third color filter CF3 may overlap the third light emitting element LD3 on one surface of the thin film encapsulation layer TFE.

The colors of the first to third color filters CF1 to CF3 may correspond to colors of light emitted from the first to third sub-pixels SP1 to SP3, respectively. For example, the first color filter CF1 is a red color filter and may include a red color filter material (for example, pigment or dye). The second color filter CF2 is a green color filter and may include a green color filter material (for example, pigment or dye). The third color filter CF3 is a blue color filter and may include a blue color filter material (for example, pigment or dye).

The color filter layer CFL further includes black matrices located between the color filters CF. For example, the color filter layer CFL may include a first black matrix BM1 located between the first color filter CF1 and the second color filter CF2, and a second black matrix BM2 located between the second color filter CF2 and the third color filter CF3. The first and second black matrices BM1 and BM2 may include at least one light blocking material and/or reflective material so that it may be configured to allow light emitted from the light emitting layer LDL to travel in the image display direction.

For example, each of the first to third color filters CF1 to CF3 may be in contact with at least one of the first or second black matrices BM1 or BM2. The first color filter CF1 may be in contact with the first black matrix BM1. The second color filter CF2 may be in contact with the first and second black matrices BM1 and BM2. The third color filter CF3 may be in contact with the second black matrix BM2. In addition, FIG. 6 illustrates a case in which adjacent color filters CF are arranged to be spaced apart from each other with the black matrix BM therebetween, but this is an example and is not limited thereto. For example, the black matrix BM located between adjacent color filters CF may be omitted. For example, when the black matrix BM is omitted, the first to third color filters CF1 to CF3 may be arranged so that the first to third color filters at least partially overlap each other. Alternatively, the first to third color filters CF1 to CF3 may be arranged to be in contact with each other.

The lens array LA may be located on the color filter layer CFL. The lens array LA may include lenses LS respectively overlapping the first to third sub-pixels SP1 to SP3. The lens array LA may collect light emitted from the light emitting layer LDL and passing through the color filter layer CFL. For example, the lens array LA may refract the light passing through the color filter layer CFL to be generally directed toward the third direction DR3. The lens array LA may serve to increase extraction efficiency of light emitted from the first to third light emitting elements LD1 to LD3.

The lens array LA may include first to third lenses LS1 to LS3. The first to third lenses LS1 to LS3 may be located on the color filter layer CFL. For example, the first lens LS1 may be located on the first color filter CF1. The second lens LS2 may be located on the second color filter CF2. The third lens LS3 may be located on the third color filter CF3.

The lens array LA may have a relatively high refractive index. For example, the lens array LA may have a higher refractive index than the overcoat layer OC. According to some embodiments, the lenses LS may include an optically transparent material. For example, the optically transparent materials may include at least one of an optically clear resin (OCR) or an optically clear adhesive (OCA). However, the material of the lenses LS is not limited thereto. For example, the lenses LS may include an acrylic material.

The first to third lenses LS1 to LS3 may have convex shapes in the third direction DR3. The cross-section of each of the first to third lenses LS1 to LS3 may have a shape that becomes thicker toward the center thereof. The first to third lenses LS1 to LS3 have a substantially convex lens shape, which may increase the light condensing effect. According to some embodiments of the present disclosure, the first to third lenses LS1 to LS3 may be formed through a photolithography process without an etching process. In this case, the first to third lenses LS1 to LS3 may include a negative photoresist composition.

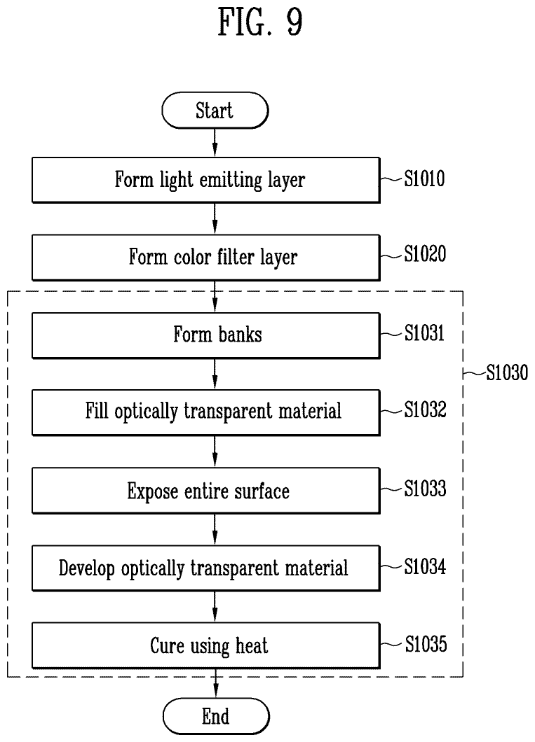

A method of manufacturing the lens array LA will be described later with reference to FIG. 9 to FIG. 16.

The overcoat layer OC may be located on the first to third lenses LS1 to LS3. The overcoat layer OC may cover the optical functional layer OFL, the encapsulation layer TFE, the light emitting layer LDL, and/or the pixel circuit layer PCL. The overcoat layer OC may include various materials suitable for protecting lower layers thereof from foreign substances such as dust and moisture. For example, the overcoat layer OC may include at least one of an inorganic insulating film or an organic insulating film. For example, the overcoat layer OC may include an epoxy resin, but embodiments are not limited thereto. The overcoat layer OC may have a lower refractive index than the lens array LA.

The cover window CW may be located on the overcoat layer OC. The cover window CW is configured to protect lower layers thereof. The cover window CW may include glass, but embodiments are not limited thereto. For example, the cover window CW may be an encapsulation glass configured to protect constituent elements located thereunder. According to some embodiments, the cover window CW may be omitted.

FIG. 7 illustrates a top plan view of one of pixels of FIG. 2 according to some embodiments.

Referring to FIG. 7, a first pixel PXL1′ may include first to third sub-pixels SP1′ to SP3′. In addition, the first to third sub-pixels SP1′ to SP3′ may include first to third color filters CF1′ to CF3′ to correspond to each sub-pixel.

The first sub-pixel SP1′ may include a first color filter CF1′ and a black matrix BM around the first color filter CF1′. The second sub-pixel SP2′ may include a second color filter CF2′ and a black matrix BM around the second color filter CF2′. The third sub-pixel SP3′ may include a third color filter CF3′ and a black matrix BM around the third color filter CF3′. However, the black matrix BM around the first to third color filters CF1′ to CF3′ may be omitted. For example, when the black matrix BM is omitted, the first to third color filters CF1′ to CF3′ may be arranged so that the first to third color filters at least partially overlap each other. Alternatively, the first to third color filters CF1′ to CF3′ may be arranged to be in contact with each other.

The first sub-pixel SP1′ and the second sub-pixel SP2′ may be arranged in the second direction DR2. The third sub-pixel SP3′ may be arranged in the first direction DR1 with respect to each of the first and second sub-pixels SP1′ and SP2′. Accordingly, the first color filter CF1′ and the second color filter CF2′ may be arranged in the second direction DR2. The third color filter CF3′ may be arranged in the first direction DR1 with respect to each of the first and second color filters CF1′ and CF2′.

The second sub-pixel SP2′ may have a larger area than the first sub-pixel SP1′, and the third sub-pixel SP3′ may have a larger area than the second sub-pixel SP2′.

Accordingly, the second color filter CF2′ may have a larger area than the first color filter CF1′, and the third color filter CF3′ may have a larger area than the second color filter CF2′. However, embodiments are not limited thereto. For example, the first and second sub-pixels SP1′ and SP2′ may have substantially the same area, and the third sub-pixel SP3′ may have a larger area than each of the first and second sub-pixels SP1′ and SP2′. As such, the areas of the first to third sub-pixels SP1′ to SP3′ may be variously changed depending on embodiments. Accordingly, the areas of the first to third color filters CF1′ to CF3′ may be variously changed depending on the first to third sub-pixels SP1′ to SP3′.

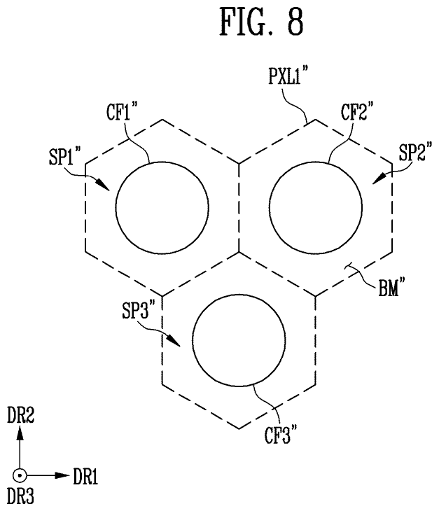

FIG. 8 illustrates a top plan view of one of pixels of FIG. 2 according to some embodiments.

Referring to FIG. 8, a first sub-pixel SP1″ may include a first color filter CF1″ and a black matrix BM around the first color filter CF1″. The second sub-pixel SP2″ may include a second color filter CF2″ and a black matrix BM around the second color filter CF2″. The third sub-pixel SP3″ may include a third color filter CF3″ and a black matrix BM around the third color filter CF3″. However, the black matrix BM around the first to third color filters CF1″ to CF3″ may be omitted. For example, when the black matrix BM is omitted, the first to third color filters CF1″ to CF3″ may be arranged so that the first to third color filters at least partially overlap each other. Alternatively, the first to third color filters CF1″ to CF3″ may be arranged to be in contact with each other.

The first to third sub-pixels SP1″ to SP3″ may have polygonal shapes when viewed in the third direction DR3. For example, the shapes of the first to third sub-pixels SP1″ to SP3″ may have hexagonal shapes as shown in FIG. 8.

The first to third color filters CF1″ to CF3″ may have circular shapes when viewed in the third direction DR3. However, embodiments are not limited thereto. For example, each of the first to third color filters CF1″ to CF3″ may have a polygonal shape.

The first and third sub-pixels SP1″ and SP3″ may be arranged in the first direction DR1. The second sub-pixel SP2″ may be arranged in a direction (or a diagonal direction) inclined by an acute angle with respect to the second direction DR2 with respect to the first sub-pixel SP1″. Accordingly, the first and third color filters CF1″ and CF3″ may be arranged in the first direction DR1. The second color filter CF2″ may be arranged in a direction (or a diagonal direction) inclined by an acute angle with respect to the second direction DR2 with respect to the first color filter CF1″.

The arrangements of the sub-pixels illustrated in FIGS. 5, 7, and 8 are merely examples, and embodiments are not limited thereto

Each pixel may include two or more sub-pixels, the sub-pixels may be variously arranged, each of the sub-pixels may have various shapes, and each of its color filters may also have various shapes.

FIG. 9 illustrates a flowchart of a method of manufacturing the display device of FIG. 6 according to some embodiments. Although various operations are illustrated in FIG. 9, embodiments according to the present disclosure are not limited thereto, and according to some embodiments, the method of manufacturing the display device may include additional operations or fewer operations, or the order of operations may vary, without departing from the spirit and scope of embodiments according to the present disclosure.

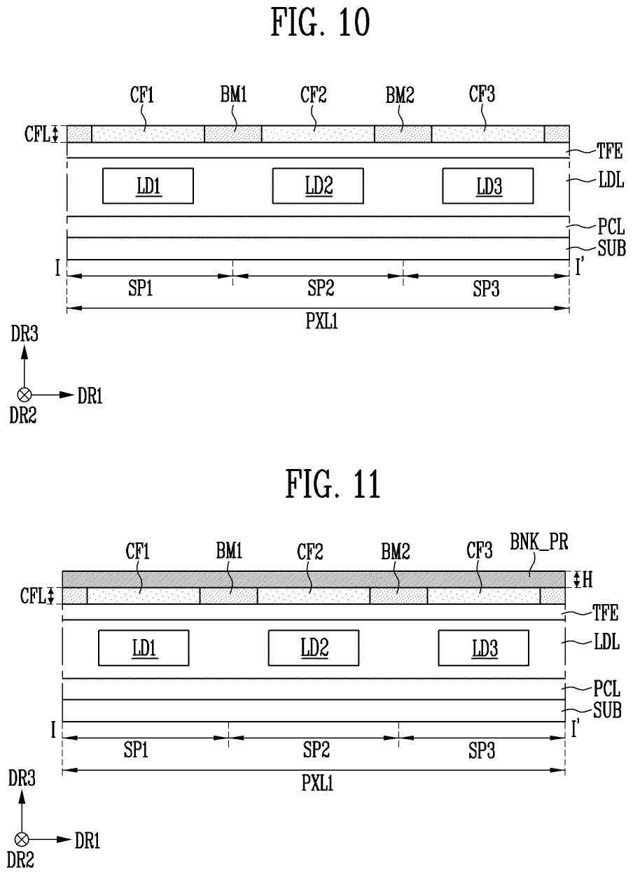

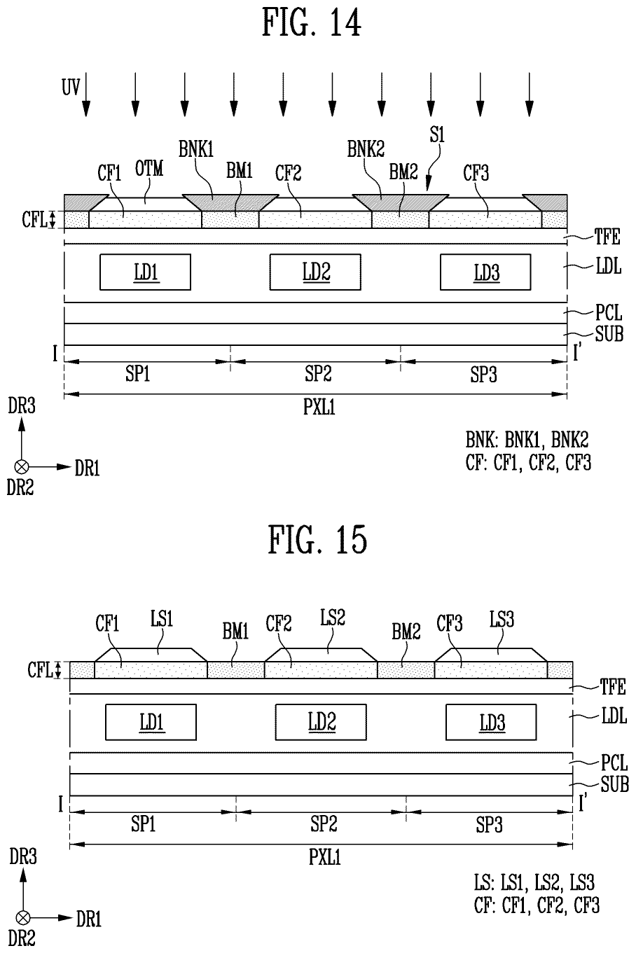

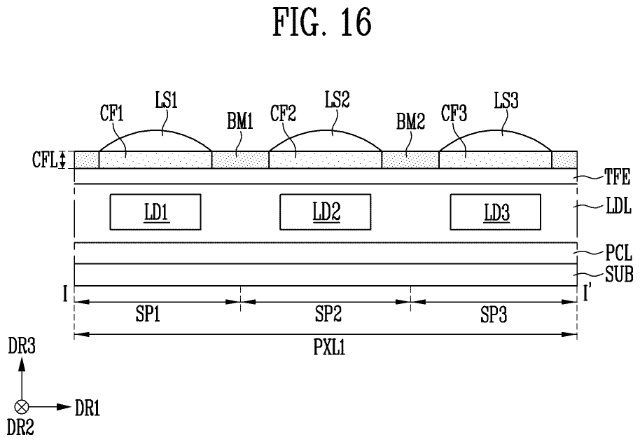

FIG. 10 illustrates a cross-sectional view of a display device in S1020 of FIG. 9. FIG. 11 to FIG. 13 illustrate cross-sectional views of a display device for explaining aspects of the operation S1031 of FIG. 9. FIG. 14 illustrates a cross-sectional view of a display device in S1033 of FIG. 9. FIG. 15 illustrates a cross-sectional view of a display device in S1034 of FIG. 9. FIG. 16 illustrates a cross-sectional view of a display device in S1035 of FIG. 9.

First, referring to FIG. 9, the method of manufacturing the display device 100 according to the embodiments of the present disclosure may include forming a light emitting layer (S1010), forming a color filter layer (S1020), and forming a lens array (S1030). In addition, the forming of the lens array (S1030) may include forming banks (S1031), filling an optically transparent material (S1032), exposing an entire surface (S1033), developing an optically transparent material (S1034), and curing using heat (S1035).

More specifically, referring to FIG. 9 and FIG. 10, in step S1010, the light emitting layer LDL including the first to third light emitting elements LD1 to LD3 may be formed on the substrate SUB. First, the pixel circuit layer PCL may be formed on the substrate SUB, and then the light emitting layer LDL may be formed on the pixel circuit layer PCL.

The first to third light emitting elements LD1 to LD3 may be formed at positions corresponding to the first to third sub-pixels SP1 to SP3, respectively. In the embodiments, the first to third light emitting elements LD1 to LD3 may include an organic light emitting diode, an inorganic light emitting element, and/or a light emitting element (quantum dot display element) that emits light by changing a wavelength of light emitted using a quantum dot. However, types of the first to third light emitting elements LD1 to LD3 are not limited thereto.

In addition, the thin film encapsulation layer TFE may be formed on the light emitting layer LDL. However, if necessary, the thin film encapsulation layer TFE may be omitted.

In S1020, the color filter layer CFL including the first to third color filters CF1 to CF3 may be formed on the thin film encapsulation layer TFE. The first to third color filters CF1 to CF3 may be formed as a single layer, and may be spaced apart from each other in the first direction DR1.

According to some embodiments, the first black matrix BM1 may be located between the first and second color filters CF1 and CF2, and the second black matrix BM2 may be located between the second and third color filters CF2 and CF3. The first and second black matrices BM1 and BM2 may be formed using carbon, titanium oxide, iron oxide, alone or in a mixture. However, the material that blocks light is not limited thereto. According to some embodiments, the first and second black matrices BM1 and BM2 may be formed by forming a material on the light emitting layer LDL and then patterning it by using a photolithography process. However, the first and second black matrices BM1 and BM2 located between the first to third color filters CF1 to CF3 May be omitted.

The first to third color filters CF1 to CF3 may be formed using inkjet, various types of coatings including slit coating, photolithography, or the like. In the case of the coating or inkjet method, a solution including each pigment and solvent may be formed in the light emitting area of each of the first to third light emitting elements LD1 to LD3. In addition, the first to third color filters CF1 to CF3 may be formed by removing the solvent through a process of curing the corresponding solution. In the case of the photolithography method, a photosensitive solution including each pigment and solution may be formed in the light emitting area of each of the first to third light emitting elements LD1 to LD3. In addition, the first to third color filters CF1 to CF3 may be formed by partially curing the solution to remove the solvent and then performing exposure and development processes.

In S1030, the lens array LA may be formed. S1030 may include S1031 to S1035.

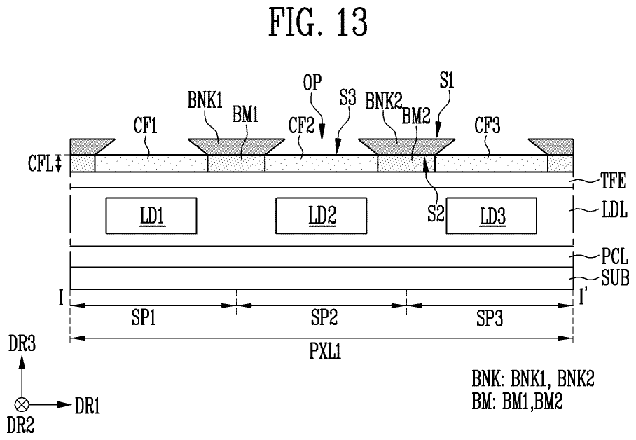

In S1031, banks BNK (see FIG. 13) may be formed. First, referring to FIG. 11, a photoresist BNK_PR for forming the banks BNK (see FIG. 13) may be applied on the color filter layer CFL. In this case, a height H of the applied photoresist BNK_PR may be about 1 μm to about 10 μm. However, it is not limited thereto, and may be about 100 μm or less depending on the design conditions of the pixels PXL.

According to some embodiments, the photoresist BNK_PR applied to form the banks BNK may include a positive photoresist composition. The positive photoresist composition may be a photoresist in which a portion to which light is not irradiated is cured. The positive photoresist composition may have physical properties such that solubility in a developing solution increases depending on the exposure amount. That is, by developing the positive photoresist composition, a pattern from which the exposed area is removed may be obtained.

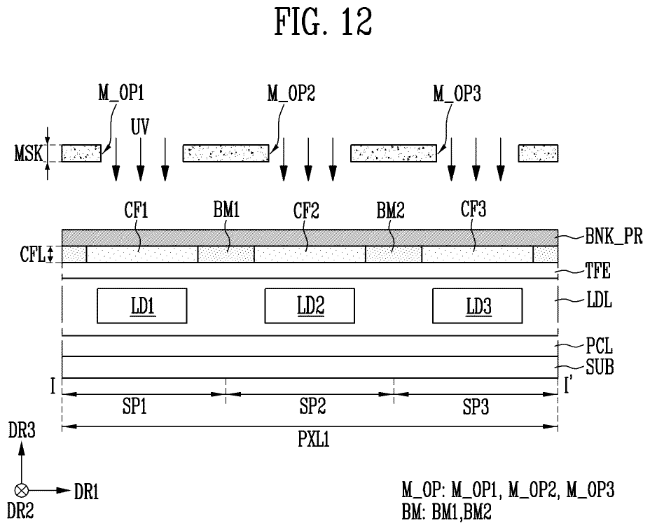

Referring to FIG. 12, the photoresist BNK_PR applied on the color filter layer CFL may be exposed through a mask MSK. Openings M_OP of the mask MSK may be located in an area in which the banks BNK are not to be formed, that is, in an area in which the lenses LS are to be formed. In addition, by irradiating ultraviolet rays UV through the openings M_OP of the mask MSK, the applied photoresist BNK_PR may be exposed. For example, the mask MSK may have a first opening M_OP1 overlapping the first color filter CF1, a second opening M_OP2 overlapping the second color filter CF2, and a third opening M_OP3 overlapping the third color filter CF3. By irradiating ultraviolet rays UV through the first to third openings M_OP1 to M_OP3 of the mask MSK, only the photoresist BNK_PR applied on the first to third colors filters CF1 to CF3 may be exposed.

Referring to FIG. 13, the banks BNK may be formed by exposing the photoresist BNK_PR exposed on the color filter layer CFL. Since the photoresist BNK_PR includes a positive photoresist composition, the photoresist BNK_PR in an area overlapping the openings M_OP of the mask MSK may be removed through exposure. In addition, the banks BNK may be formed by applying heat to the photoresist BNK_PR in an area that does not overlap the openings M_OP of the mask MSK. For example, the photoresist BNK_PR on the first to third color filters CF1 to CF3 overlapping the first to third openings M_OP1 to M_OP3 of the mask MSK may be removed. On the other hand, the photoresists BNK_PR on the first and second black matrices BM1 and BM2 that do not overlap the first to third openings M_OP1 to M_OP3 of the mask MSK may remain. In addition, the banks BNK may be formed from photoresists BNK_PR on the first and second black matrices BM1 and BM2. The banks BNK formed as described above may include a first bank BNK1 overlapping between the first color filter CF1 and the second color filter CF2, and a second bank BNK2 overlapping between the second color filter CF2 and the third color filter CF3.

The banks BNK may have a reverse tapered shape. Each of the first to third banks BNK1 to BNK3 may have a cross-sectional shape in which a cross-sectional area becomes narrower from an upper surface S1 to a lower surface S2. According to some embodiments, the reverse tapered shape of each of the first to third banks BNK1 to BNK3 may be formed by adjusting exposure energy, exposure angle, and the like when exposing the photoresist BNK_PR.

The openings OP may be formed between the banks BNK, so that the upper surface S3 of each color filter CF may be exposed.

Referring to FIG. 9 and FIG. 14, in S1032, the openings OP between the banks BNK may be filled with an optically transparent material OTM. The optically transparent material OTM may be filled into the openings OP between the banks BNK through an inkjet process or a filling process. For example, the optical transparent material OTM may be filled between the first bank BNK1 and the second bank BNK2 so that it may directly contact the second color filter CF2.

According to some embodiments of the present disclosure, the optically transparent material OTM filled to form the lenses LS may include a negative photoresist composition. The negative photoresist composition may be a photoresist in which a portion to which light is irradiated is cured. The negative photoresist composition may have physical properties such that solubility in a developing solution decreases depending on the exposure amount. That is, by developing the negative photoresist composition, a pattern corresponding to the exposed area may be obtained.

According to some embodiments, the banks BNK may include a liquid-repellent material. The banks BNK may push the optically transparent material OTM because the contact angle with the optically transparent material OTM is relatively large due to the liquid-repellent material. The liquid-repellent material configuring the banks BNK may include an organic polymer material. For example, the liquid-repellent material may include a polymer material in which a fluoro group (F) is mixed with an organic material such as polyimide. Accordingly, the banks BNK may have hydrophobicity as a liquid-repellent material. According to some embodiments, the banks BNK may have hydrophobicity on their respective upper surfaces S1. As the banks BNK have hydrophobicity, the optically transparent material OTM may be stably filled into the openings OP between the banks BNK and may not remain on the upper surface S1 of each of the banks BNK. In addition, due to a pinning phenomenon, the optically transparent material OTM may not overflow from the openings OP between the banks BNK.

In S1033, the banks BNK and the optically transparent material OTM may be entirely exposed without a separate mask. By irradiating ultraviolet rays UV in a direction opposite to the third direction DR3, respective upper surfaces of the banks BNK and the optically transparent material OTM may be entirely exposed.

Referring to FIG. 9 and FIG. 15, in S1034, by developing the exposed banks BNK and the exposed optically transparent material OTM, the exposed banks BNK may be removed and the exposed optically transparent material OTM may be left. The lenses LS may be formed from the optically transparent material OTM left on the color filters CFs. According to some embodiments, since the first and second banks BNK1 and BNK2 include a positive photoresist composition, the solubility in the developer may increase due to exposure in S1033. The first and second banks BNK1 and BNK2 may be removed through development. On the other hand, since the optically transparent material OTM overlapping each of the first to third color filters CF1 to CF3 includes a negative photoresist composition, the solubility in the developer may be reduced due to exposure in S1033. The optically transparent material OTM overlapping each of the first to third color filters CF1 to CF3 may form the first to third lenses LS1 to LS3.

In this way, by using the positive photoresist composition and the negative photoresist composition together, the pattern of the lens array may be formed with only one exposure. That is, the banks BNK including the positive photoresist composition may be removed through exposure, and the patterns of the lenses LS including the negative photoresist composition may be left through exposure.

According to some embodiments, the first to third lenses LS1 to LS3 may be spaced apart from each other in the first direction DR1. The first lens LS1 may be located on the color filter layer CFL to overlap the first color filter CF1. The second lens LS2 may be located on the color filter layer CFL to overlap the second color filter CF2. The third lens LS3 may be located on the color filter layer CFL to overlap the third color filter CF3.

Referring to FIG. 15, the lenses LS may have a tapered shape. Each of the lenses LS may have a trapezoidal cross-sectional shape. According to some embodiments, the lenses LS may have a shape complementary to the shape of the banks BNK. For example, when the banks BNK have a reverse tapered shape, the lenses LS may have a tapered shape.

Referring to FIG. 9 and FIG. 16, in S1035, the first to third lenses LS1 to LS3 may be cured. After exposure in S1033 and development in S1034, the first to third lenses LS1 to LS3 may be cured using heat. Through heat curing, the positive photoresist composition configuring the first to third lenses LS1 to LS3 may partially flow. Accordingly, the first to third lenses LS1 to LS3 may have gently curved convex shapes. Particularly, when heat curing is performed at a low temperature of about 100° C. or less, for example, fine patterning of the lens array may be possible.

Thereafter, the overcoat layer OC (see FIG. 6) may be formed on the first to third lenses LS1 to LS3. The overcoat layer OC may provide a planarized upper surface on the first to third lenses LS1 to LS3.

In the display device and the method of manufacturing the same according to the embodiments of the present disclosure, by forming a fine pattern of the lens array through photolithography without a separate etching process, defects such as increased roughness, under-etching, and over-etching occurring in the etching process may be removed. In addition, the mask pattern process for etching may be omitted, thereby reducing manufacturing costs due to reduced processes.

According to some embodiments of the present disclosure, a display device with relatively improved reliability and a method of manufacturing the same are provided.

The characteristics of embodiments of the present disclosure are not limited by what is illustrated in the above, and more various effects are included in the present specification.

Although aspects of some embodiments and implementations have been described herein, other embodiments and modifications will be apparent from this description. Accordingly, embodiments according to the present disclosure are not limited to the embodiments specifically described herein, but rather to the broader scope of the presented claims and various obvious modifications and equivalent arrangements.

What is claimed is:

1. A display device comprising:
a substrate;
a pixel circuit layer on the substrate;
a light emitting layer on the pixel circuit layer and including light emitting elements;
a color filter layer on the light emitting layer and including color filters; and
a lens array on the color filter layer,
wherein the lens array includes a plurality of lenses having convex shapes in a direction opposite to a direction toward the substrate, and
the plurality of lenses include a negative photoresist composition.

2. The display device of claim 1, wherein the plurality of lenses include an optically transparent material.

3. The display device of claim 1, wherein the plurality of lenses respectively overlap the color filters.

4. The display device of claim 1, wherein the color filters include a first color filter, a second color filter, and a third color filter spaced apart from each other in a first direction,
the plurality of lenses include a first lens on the first color filter, a second lens on the second color filter, and a third lens on the third color filter, and
each of the first to third lenses has a convex shape.

5. The display device of claim 1, wherein the color filters respectively overlap the light emitting elements.

6. A method of manufacturing a display device, comprising:
forming a light emitting layer on a substrate;
forming a color filter layer including color filters on the light emitting layer; and
forming a lens array on the color filter layer, wherein the lens array includes a plurality of lenses having convex shapes in a direction opposite to a direction toward the substrate,
wherein the forming of the lens array comprises:
forming banks on the color filter layer;
filling an optically transparent material between the banks;
entirely exposing the banks and the optically transparent material;
removing, by developing the exposed banks and the exposed optically transparent material, the exposed banks while leaving the exposed optically transparent material; and
curing the remaining optically transparent material to form the plurality of lenses.

7. The method of manufacturing the display device of claim 6, wherein the plurality of lenses include a negative photoresist composition.

8. The method of manufacturing the display device of claim 6, wherein by curing the remaining optically transparent material using heat, the convex shapes of the plurality of lenses are formed.

9. The method of manufacturing the display device of claim 6, wherein the plurality of lenses respectively overlap the color filters.

10. The method of manufacturing the display device of claim 6, wherein forming the banks includes:
applying a photoresist on the color filter layer;
exposing the photoresist using a mask; and
developing the exposed photoresist to form the banks.

11. The method of manufacturing the display device of claim 6, wherein each of the banks has a reverse tapered shape.

12. The method of manufacturing the display device of claim 6, wherein the banks include a positive photoresist composition.

13. The method of manufacturing the display device of claim 6, wherein the banks include a liquid-repellent material.

14. The method of manufacturing the display device of claim 13, wherein a portion adjacent to an upper surface of each of the banks has hydrophobicity.

15. The method of manufacturing the display device of claim 6, wherein the color filters include a first color filter, a second color filter, and a third color filter spaced apart from each other in a first direction, and
the banks include a first bank overlapping between the first color filter and the second color filter and a second bank overlapping between the second color filter and the third color filter.

16. The method of manufacturing the display device of claim 15, wherein the optically transparent material directly contacts the second color filter between the first bank and the second bank.

17. The method of manufacturing the display device of claim 15, wherein the plurality of lenses include a first lens on the first color filter, a second lens on the second color filter, and a third lens on the third color filter, and
each of the first to third lenses has a convex shape.
